(19) United States
(12) Patent Application Publication
(10) Pub. No.: US 2007/0014345 A1
(43) Pub. Date: Jan. 18, 2007

(54) Low complexity Tomlinson-Harashima precoders

(75) Inventors: Yongru Gu, Minneapolis, MN (US); Keshab K. Parhi, Maple Grove, MN (US)

Correspondence Address: Keshab K. Parhi, 6600 Fountain Lane N., Maple Grove, MN, 55311, US

(73) Assignee: Leanics Corporation

(21) Appl. No.: 11/181,348

(22) Filed: Jul. 13, 2005

(51) Int. Cl. H03K 5/159; H04L 27/00

(52) U.S. Cl. 375/232; 375/259

(57) ABSTRACT

A method to design low complexity pipelined Tomlinson-Harashima precoders and its associated circuit architectures have been described. The low complexity pipelined TH precoder design relies on the proposed low complexity precomputation based FIR filters. In the low complexity precomputation method for FIR filters, each multiplier is replaced with a multiplexer.

### STATEMENT REGARDING FEDERALLY-SPONSORED RESEARCH AND DEVELOPMENT

This invention was made with Government support under the SBIR grant #DMI-0441632, awarded by the National Science Foundation. The Government has certain rights in this invention.

### FIELD OF THE INVENTION

The present invention relates to data processing and transmission. More particularly, it relates to Tomlinson-Harashima precoding of data and Tomlinson-Harashima precoders.

### BACKGROUND OF THE INVENTION

Tomlinson-Harashima preceding (TH preceding) is a transmitter equalization technique where equalization is performed at the transmitter side, and has been widely used in many communication systems. It can eliminate error propagation and allows use of capacity-achieving channel codes, such as low-density parity-check (LDPC) codes, in a natural way.

Recently, TH precoding has been proposed to be used in 10 Gigabit Ethernet over copper transceivers. The symbol rate of 10GBASE-T is 800 Mega Baud. However, a TH precoder contains feedback loops, and it may be impossible to clock the straightforward implementation of the TH precoder at such high speed. Thus, high speed design of TH precoders is of great interest.

How to design a fast TH precoder is a challenging task. The architecture of a TH precoder is similar to that of a DFE (decision feedback equalizer). The only difference is that a quantizer in the DFE is replaced with a modulo device in the TH precoder. In a PAM-M (M-level pulse amplitude modulation) system, the number of different outputs of the quantizer in the DFE is finite, which is usually equal to the size of the symbol alphabet, i.e., M. However, theoretically, the number of different outputs of the modulo device in the TH precoder is infinite for a floating-point implementation. For a fixed-point implementation, it grows in an exponential manner with the wordlength. In some applications, the wordlength can be very large. Thus, many known techniques, which exploit the property of finite-level outputs of the nonlinear elements in the DFE, such as the pre-computation technique (See, e.g., in K. K. Parhi, “Pipelining in algorithms with quantizer loops,” IEEE Trans. on Circuits and Systems, vol. 37, no. 7, pp. 745-754, July 1991), cannot be directly applied to pipeline the TH precoder. Furthermore, the use of look-ahead techniques in the TH precoder, such as those for pipelining infinite impulse response (IIR) filters (See, e.g., K. K. Parhi and D. G. Messerschmitt, “Pipeline interleaving and parallelism in recursive digital filters, Part I and Part II,” IEEE Trans. Acoust., Speech, Signal Processing, pp. 1099-1135, July 1989), is not straightforward as the TH precoder contains nonlinear elements in the feedback loop.

It is well known that a TH precoder can be viewed as an IIR filter with an input equal to the sum of the original input to the TH precoder and a finite-level compensation signal. Based on that observation, Y. Gu and K. K. Parhi ( See. Y. Gu and K. K. Parhi, “Pipelining Tomlinson-Harashima Precoders”, in Proc. of 2005 IEEE International Symposium on Circuits and Systems, pp 408-411, Kobe, Japan, May 2005) proposed a method to pipeline TH precoders. This method requires the precomputation of the output of an L-tap FIR (finite impulse response) filter. If the number of possibilities of the input to the FIR filter is S, then we need to precompute S^{L} outputs and require a W-bit S^{L}-to-1 multiplexer to select the correct output. When L and S are large, the hardware overhead associated with the precomputation is formidable. Thus, it is of interest to develop low complexity pipelined TH precoders.

What is needed is a pipelined TH precoder with low hardware overhead and a method for designing the same, which can fully exploit the properties of a TH precoder.

### BRIEF SUMMARY OF THE INVENTION

The present invention provides a low complexity pipelined TH precoder and a method for designing the same.

In accordance with the present invention, a TH precoder is first converted to its equivalent IIR filter form. Next, classical look-ahead techniques are applied to pipeline the IIR filter. Then, the pipelined IIR filter is reformulated into a structure which consists of a pipelined loop and a non-pipelined loop with a finite-level input. Finally, a low complexity precomputation technique is applied to the non-pipelined loop.

Further embodiments, features, and advantages of the present invention, as well as the structure and operation of the various embodiments of the present invention are described in detail below with reference to accompanying drawings.

### BRIEF DESCRIPTION OF THE DRAWINGS/FIGURES

The present invention is described with reference to the accompanying figures. The accompanying figures, which are incorporated herein and form part of the specification, illustrate the present invention and, together with the description, further serve to explain the principles of the invention and to enable a person skilled in the relevant art to use the invention.

FIG. 1 illustrates the idea of Tomlinson-Harashima preceding.

FIG. 2 shows the straightforward architecture of a 2nd-order FIR TH precoder.

FIG. 3 illustrates a TH precoder and its pipelined equivalent forms.

FIG. 4 illustrates two intermediate pipelined TH precoders.

FIG. 5 illustrates the pipelined TH precoder.

FIG. 6 illustrates an example for a 2-level pipelined TH precoder.

FIG. 7 shows a modified pipelined TH precoder.

FIG. 8(a) illustrates an IIR TH precoder where H(z) is an IIR filter.

FIG. 8(b) shows an equivalent form of an IIR TH precoder.

FIG. 8(c) illustrates another equivalent form of an IIR TH precoder.

FIG. 8(d) shows the pipelined equivalent form of an IIR TH precoder.

FIG. 9 shows a multiplier and its precomputation based implementation.

FIG. 10 illustrate one possible implementation of a 16-to-1 multiplexer.

FIG. 11 illustrates a 2-tap FIR filter and it straightforward precomputation architecture.

FIG. 12 illustrates a 3-tap FIR filter and it straightforward precomputation architecture.

FIG. 13 illustrates the proposed low complexity precomputation architectures for a 2-tap FIR filter and a 3-tap FIR filter.

FIG. 14 shows an L-tap FIR filter.

FIG. 15 illustrates an example for a low complexity pipelined precoder.

### DETAILED DESCRIPTION OF THE INVENTION

### Background on Tomlinson-Harashima Precoding

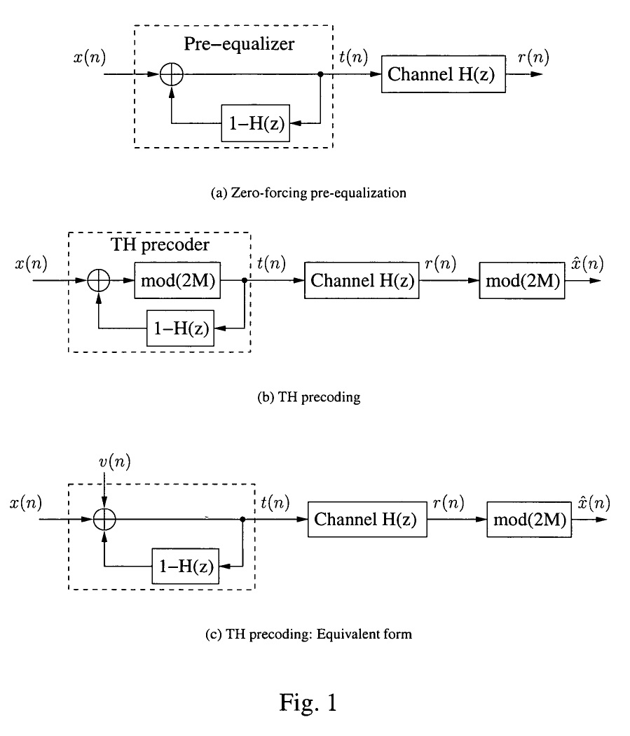

Consider a discrete-time channel described by an FIR model

$$H ( z ) = 1 + {\sum }_{i = 1}^{{L}_{H}} {h}_{i} {z}^{- i} , \qquad EQ . ( 1 )$$

where L_{H} is the channel memory length. We assume that the model is known at the transmitter side. We also assume that the transmitted symbols are PAM-M symbols, where the symbol set is {±1, ±3, . . . , ±(M−1)}. To remove inter-symbol interference (ISI), we can use zero-forcing pre-equalization, which basically implements the inverse of the channel transfer function at the transmitter side, as illustrated in FIG. 1(a). However, one problem associated with the scheme in FIG. 1(a) is that the output of the pre-equalizer has a large dynamic range, which may even be unlimited.

Tomlinson and Harashima (See, M. Tomlinson, “New automatic equalizer employing modulo arithmetic,” Electron. Lett., vol. 7, pp. 138-139, March 1971; and H. Harashima and H. Miyakawa, “Matched-transmission technique for channels with intersymbol interference,” IEEE Trans. Commun., vol. 20, pp. 774-780, August 1972) proposed to limit the output dynamic range by using a nonlinear modulo device in the feedforward path of the pre-equalizer, as shown in FIG. 1(b). The resulting pre-equalizer is called a TH precoder (More specifically, since H(z) is an FIR filter, we can call the TH precoder an FIR TH precoder). The operation of TH preceding can be interpreted by using the equivalent form of the TH precoder in FIG. 1(c). A unique compensation signal v(n), which is a multiple of 2M, is added to the transmitted PAM-M signal x(n) such that the output of the precoder t(n) is limited in the interval [−M, M). So the effective transmitted data sequence in z-domain is

$$T ( z ) = \frac{X ( z ) + V ( z )}{H ( z )} . \qquad EQ . ( 2 )$$

The received signal is

$$R ( z ) = H ( z ) \frac{X ( z ) + V ( z )}{H ( z )} = X ( z ) + V ( z ) , \qquad EQ . ( 3 )$$

and X(z) can be recovered from R(z) by performing a modulo operation. An important property of v(n) is that it only has finite levels since v(n) is a multiple of 2M and |v(n)|≦(1+ΣLᵢ₌₁^{L}^{_{H}}|hᵢ|)M.

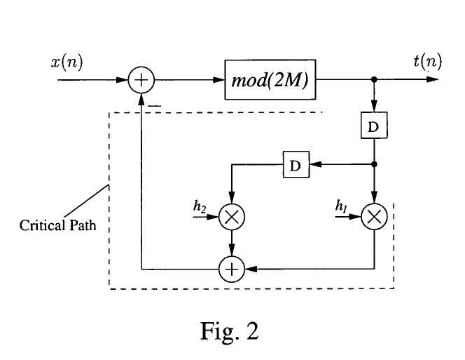

FIG. 2 shows the straightforward architecture of a 2nd-order FIR TH precoder. It has a critical path consisting of one multiplier, two adders and one modulo device. The computation time of the critical path is
T_{Critical}=2Tₐ+Tₘ+T_{mod}, EQ.(4)
where Tₐ, Tₘ and T_{mod} denote the computation times of an addition, a multiplication and a modulo operation, respectively (Note: T_{mod}=0 when M is a power of 2). From the figure, we can see that the iteration bound, T_{∞} (For the definition of iteration bound, please see K. K. Parhi, VLSI Digital Signal Processing Systems Design and Implementation, John Wiley & Son, Inc., New York, 1999), of the architecture is also equal to T_{Critical}) i.e.,
T_{∞}=T_{Critical}=2Tₐ+Tₘ+T_{mod}. EQ.(5)
The achievable minimum clock period of this architecture is limited by T_{∞}, i.e., we cannot operate the precoder at a speed higher than 1/T_{∞}. Classical high-speed design techniques such as retiming and unfolding cannot be used to achieve higher speed since the iteration bound is a fundamental limit. Thus it is important to develop techniques to design a fast TH precoder.

### Background on Pipelined Tomlinson-Harashima Precoders

In this section, a brief review on pipelining TH precoders is reviewed (For detail, please see, Y Gu and K. K. Parhi, “Pipelining Tomlinson-Harashima Precoders”, in Proc. of 2005 IEEE International Symposium on Circuits and Systems, pp 408-411, Kobe, Japan, May 2005).

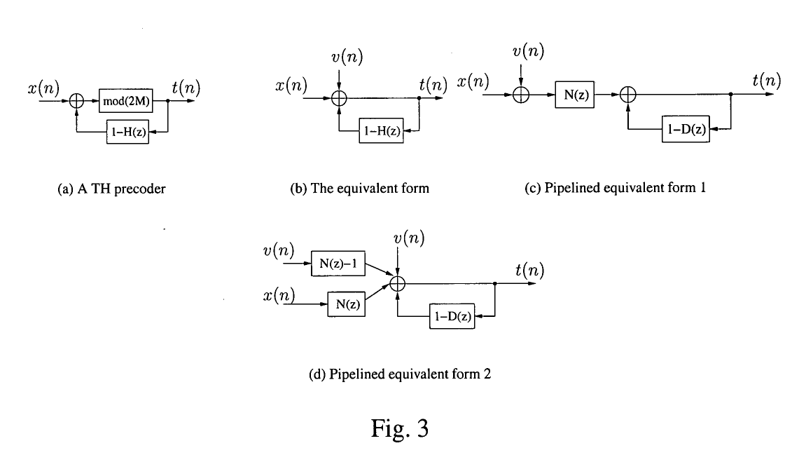

FIGS. 3 through 5 show the steps to pipeline a TH precoder in Gu and Parhi. The first step is to convert the TH precoder in FIG. 3(a) into its IIR filter equivalent form shown in FIG. 3(b). The second step involves pipelining the IIR filter 1/H(z). Many approaches, such as the clustered and the scattered look-ahead approaches in K. K. Parhi, VLSI Digital Signal Processing Systems Design and Implementation, John Wiley & Son, Inc., New York, 1999, can be used to pipeline the IIR filter. In both of these approaches, the pipelined filter Hₚ(z) is obtained by multiplying an appropriate polynomial N(z)=n1+Σᵢ₌₁^{L}^{_{N}}nᵢz⁻ⁱ to both the numerator and the denominator of the transfer function of the original IIR filter

$${H}_{p} ( z ) = \frac{N ( z )}{H ( z ) N ( z )} = \frac{N ( z )}{D ( z )} . \qquad EQ . ( 6 )$$

The pipelined filter Hₚ(z) consists of two parts, an FIR filter N(z) and an all-pole pipelined IIR filter 1/D(z), as shown in FIG. 3(c). In the case of the clustered look-ahead approach, D(z) can be expressed in the form of

$$D ( z ) = 1 + {z}^{- K} {\sum }_{i = 1}^{K + {L}_{H}} {d}_{i} {z}^{- ( i - 1 )} , \qquad EQ . ( 7 )$$

and, for the scattered look-ahead approach

$$D ( z ) = 1 + {\sum }_{i = 1}^{{L}_{H}} {d}_{i} {z}^{- iK} , \qquad EQ . ( 8 )$$

where K is the pipelining level, and K is dependent on the coefficients of the filters N(z) and H(z).

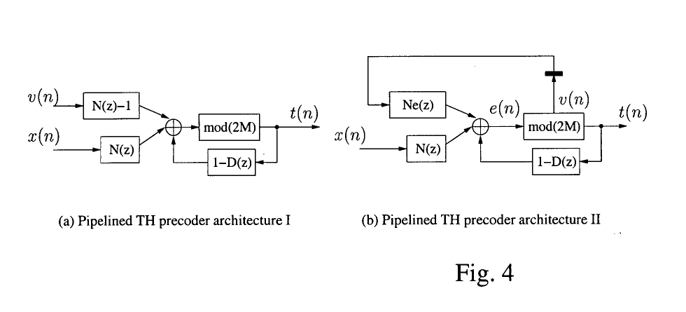

The design in FIG. 3(c) is not implementable as one of the current inputs, v(n), of the pipelined IIR filter is dependent on the current output of the IIR filter. However, we can redraw the design in FIG. 3(c) and obtain a new design as shown in FIG. 3(d). To remove the explicit input v(n) to the all-pole IIR filter 1/D(z) in FIG. 3(d), we can introduce a modulo operation in its feedforward path, leading to the design illustrated in FIG. 4(a).

Let us define

$${N}_{e} ( z ) = {\sum }_{i = 1}^{{L}_{N}} {n}_{i} {z}^{- i + 1} = z ( N ( z ) - 1 ) , \qquad EQ . ( 9 )$$

then we can redraw FIG. 4(a) and obtain FIG. 4(b), where the input to the FIR filter Nₑ(z) is a delayed version of the compensation signal v(n).

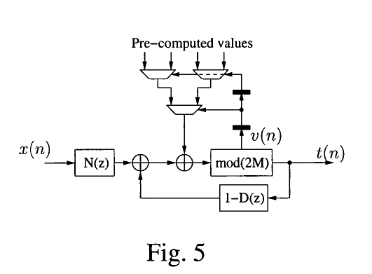

As we can see from FIG. 4(b), there are mainly two nonlinear feedback loops in the design. One is the pipelined loop containing the FIR filter 1−D(z). The other is the non-pipelined nonlinear loop containing the FIR filter Nₑ(z). The speed of the design is limited by the non-pipelined loop. However, like feedback loops in DFEs, the compensation signal v(n) in the non-pipelined loop only takes finite number of different values. Thus we can pre-compute all possible outputs of the FIR filter Nₑ(z) as in the pre-computation technique for quantizer loops in K. K. Parhi, “Pipelining in algorithms with quantizer loops,” IEEE Trans. on Circuits and Systems, vol. 37, no. 7, pp. 745-754, July 1991. Assume Nₑ(z) only has two taps, then we can obtain an architecture as shown in FIG. 5.

Consider an example where the channel transfer function H(z)=1+h₁z⁻¹+h₂z⁻². The transfer function Hₑ(z) of the zero-forcing pre-equalizer is

$${H}_{e} ( z ) = \frac{1}{H ( z )} = \frac{1}{1 + {h}_{1} {z}^{- 1} + {h}_{2} {z}^{- 2}} . \qquad EQ . ( 10 )$$

A 2-level scattered look-ahead pipelined design of the IIR filter Hₑ(z) can be obtained by multiplying N(z)=1−h₁z⁻¹+h₂z⁻² to the numerator and the denominator of Hₑ(z)

$${H}_{p} ( z ) = \frac{1 - {h}_{1} {z}^{- 1} + {h}_{2} {z}^{- 2}}{1 + ( 2 {h}_{2} - {h}_{1}^{2} ) {z}^{- 2} + {h}_{2}^{2} {z}^{- 4}} . \qquad EQ . ( 11 )$$

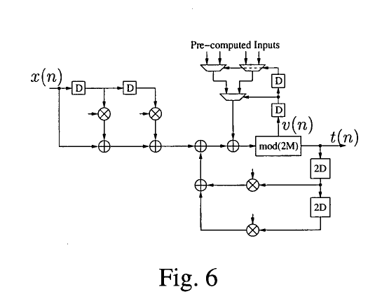

Applying the techniques in FIGS. 3 through 5 to the example, we can obtain a pipelined precoder design shown in FIG. 6. The iteration bound T_{∞} of this design is given by

$${T}_{∞} = max \{ \frac{3 {T}_{a} + {T}_{mod} + {T}_{m}}{2} , {T}_{a} + {T}_{mod} + {T}_{mux} \} , \qquad EQ . ( 12 )$$

where Tₘᵤₓ is the operation time of a multiplexer. Assume Tₘ dominates the computation time, then the design in FIG. 6 can achieve a speedup of 2.

One problem associated with the design in FIG. 5 is the hardware overhead. The overhead due to pre-computation is exponential with the number of taps of the FIR filter Nₑ(z). When the number of taps is large, the hardware overhead is formidable. To reduce the overhead, we can just apply precomputation to the first few taps of the FIR filter Nₑ(z) in FIG. 4(b). For example, we can partition Nₑ(z) into two parts

$${N}_{e} ( z ) = {N}_{e 1} ( z ) + {z}^{- {L}_{1}} {N}_{e 2} ( z ) , \\ where \\ {N}_{e 1} ( z ) = {\sum }_{i = 1}^{{L}_{1}} {n}_{i} {z}^{- ( i - 1 )} , \\ and \\ {N}_{e 2} ( z ) = {\sum }_{i = {L}_{1} + 1}^{{L}_{N}} {n}_{i} {z}^{- ( i - {L}_{1} - 1 )} . \qquad EQ . ( 13 )$$

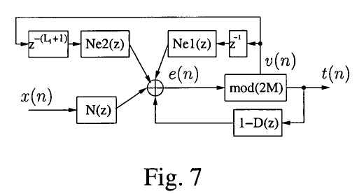

Then, redrawing the design in FIG. 4(b), we can obtain a new design shown in FIG. 7. For a low-complexity design, we can only pre-compute all possible outputs of the FIR filter Nₑ₁(z).

The pipelining technique for FIR TH precoders in Y Gu and K. K. Parhi, “Pipelining Tomlinson-Harashima Precoders”, in Proc. of 2005 IEEE International Symposium on Circuits and Systems, pp 408-411, Kobe, Japan, May 2005, can also be applied to design pipelined IIR TH precoder where H(z) in EQ. 1 and FIG. 1 is described by an IIR model

$$H ( z ) = \frac{B ( z )}{A ( z )} , \qquad EQ . ( 14 )$$

where A(z)=1+ΣLᵢ₌₁^{L}^{_{A}}aᵢz⁻ⁱ and B(z)=1+Σᵢ₌₁^{L}^{_{B}}bᵢz⁻ⁱ.

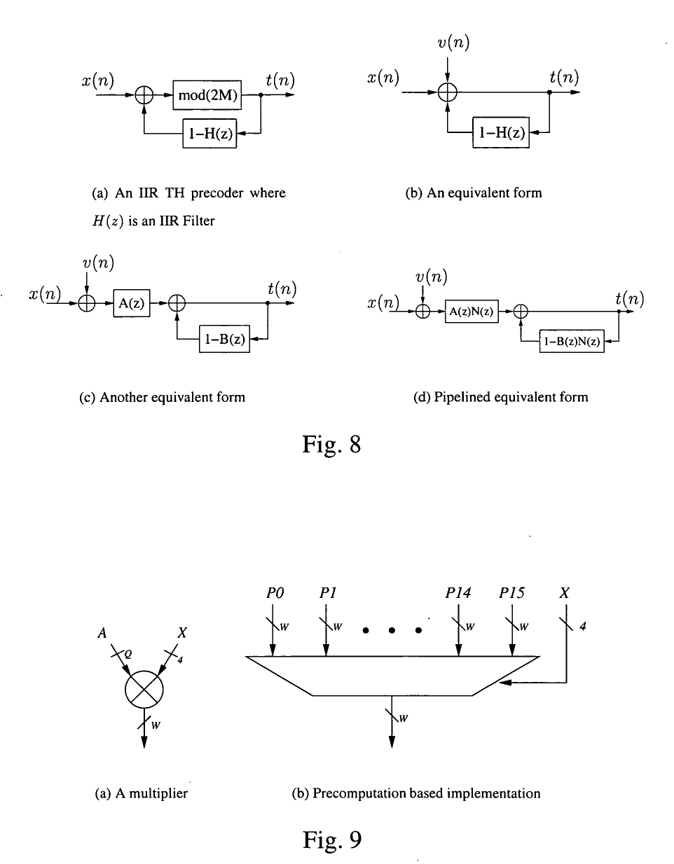

FIG. 8(a) shows the block diagram of an IIR TH precoder with H(z)=B(z)/A(z). Its equivalent form is shown in FIG. 8(b). We can redraw FIG. 8(b) and obtain another equivalent form shown in FIG. 8(c). The speed of the design is limited by the speed of the IIR filter 1/B(z). Again, we can apply some well-known pipelining techniques, such as the clustered and the scattered look-ahead approaches, to remove this bound, resulting in a new design shown in FIG. 8(d), where N(z)=Σᵢ₌₁^{L}^{_{N}}nᵢz⁻ⁱ is a pipelining polynomial. Then, we can apply the same techniques presented in FIGS. 3, 4 and 5 to FIG. 8(d) to pipeline the IIR TH precoder. We can also use the technique in FIG. 7 to reduce the complexity of the fully pre-computed design.

### Problem in Pipelined Tomlinson-Harashima Precoders

In some applications, the number of levels of v(n) may be very large. Thus, even if we just precompute the first three taps of the FIR filter Nₑ(z) as in FIG. 7, the hardware overhead may still be significant. For example, if we assume that v(n) has 16 levels and we want to precompute 3 taps, then we need to totally precompute 16³=4096 candidates and select the actual one by a 4096-to-1 W-bit multiplexer array, where W is the wordlength requirement. Thus it is of interest to develop techniques to reduce the hardware complexity associated with precomputation. Thus, a low complexity pipelined TH precoder is needed and a method to design the same is also needed.

### The Straightforward Precomputation for FIR Filters

FIG. 9(a) shows a multiplier which needs to implement the multiplication of A×X where A is a constant. For simplicity, assume that X can be represented by a binary number of 4 bits and can take 16 possible values. We also assume that A is a Q-bit binary number and the product can be represented by a W-bit binary number. Obviously, the product of A×X also has 16 possibilities. We denote these 16 possibilities, P0, P1, . . . , P14, and P15, and they can be precomputed. The 16 precomputed candidates are input to a 16-to-1 W-bit multiplexer. The real product is selected from the 16 candidates by the signal X, as shown in FIG. 9(b).

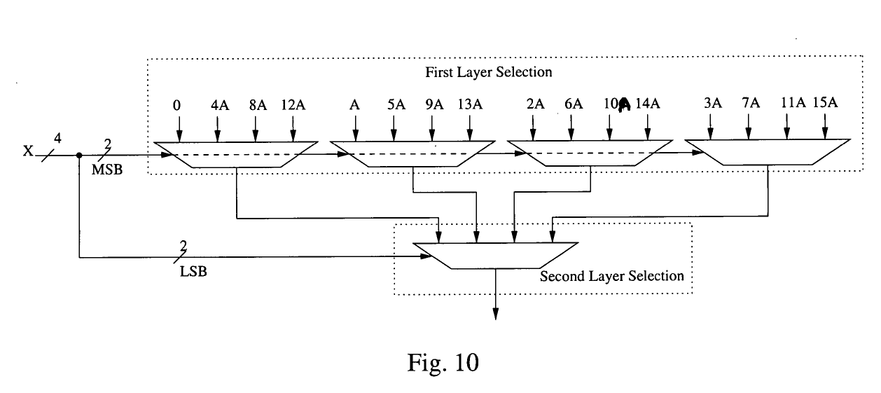

There are many different ways to implement the 16-to-1 multiplexer in FIG. 9(b). FIG. 10 illustrates one method to implement the multiplexer by using a two-layer 4-to-1 multiplexer array. For simplicity, we assume that X can be represented by a 4-bit unsigned binary number
X=x₃x₂x₁x₀, EQ.(15)
where the bits xᵢ, i=0, 1, 2, and 3, are either 0 or 1. The value of this number is in the range of [0, 15] and is given by:
X=x₃2³+x₂2²+x₁2+x₀. EQ.(16)
The 16 possible outputs of the multiplication A x X are 0, A, 2A, . . . , 14A and 15A, respectively. In FIG. 10, the most significant two bits (MSB) of X, x₃ and x₂, are used as the select signals for the first layer selection which select one of subsets from subsets {0, A, 2A, 3A}, {4A, 5A, 6A, 7A}, {8A, 9A, 10A, 11A}, and The least significant two bits (LSB) of X, x₁ and x₀, are used as the select signals for the second layer selection which select one of products in the subset obtained from the first layer selection.

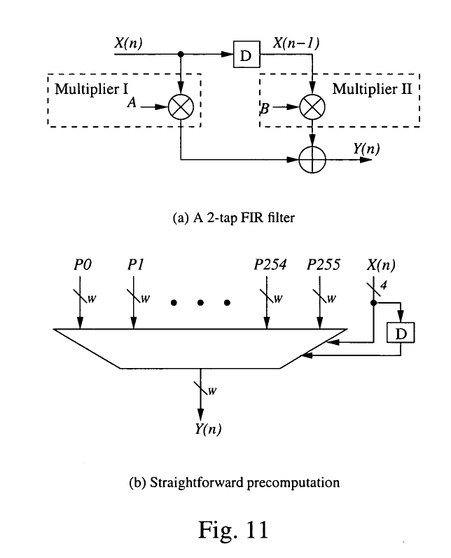

FIG. 11(a) shows a two-tap FIR filter. Assume that the input, X(n), to the FIR filter also has 16 possibilities. Then, both of the outputs of the multiplier I and multiplier II have 16 possibilities. Hence, the output, Y(n), of the FIR filter has 16²=256 possibilities. These possibilities, denoted as P0, P1, . . . , P254, and P255, can be precomputed. In the straightforward precomputation approach, the FIR filter can be implemented by a W-bit 256-to-1 multiplexer, where W is the wordlength requirement of the product. As shown in FIG. 11(b), the inputs to the multiplexer are the 256 precomputed candidates, and the select signals are X(n) and X(n−1).

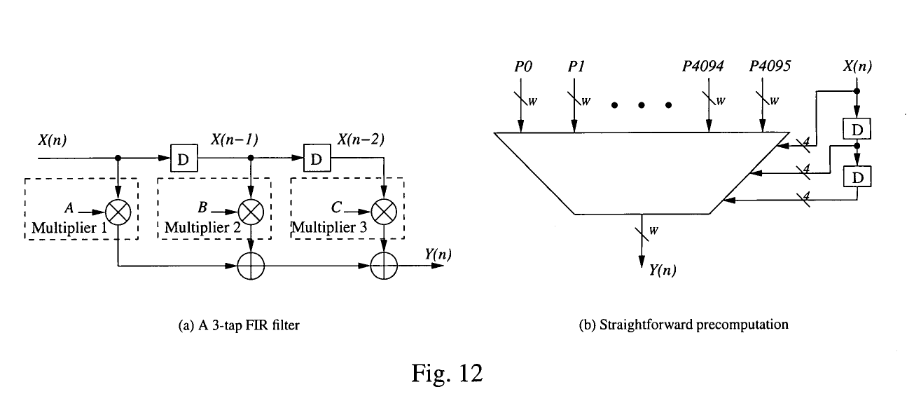

FIG. 12(a) shows a 3-tap FIR filter. Assume that the input, X(n), to the FIR filter also has 16 possibilities. Then, all of the outputs of multipliers I, II and III have 16 possibilities. Hence, the output, Y(n), of the FIR filter has 16³=4096 possibilities. These possibilities, denoted as P0, P1, . . . , P4094, and P4095, can be precomputed. In the straightforward precomputation approach, the FIR filter can be implemented by a W-bit 4096-to-1 multiplexer, where W is the wordlength requirement of the product. As shown in FIG. 12(b), the inputs to the multiplexer are the 4096 precomputed candidates, and the select signals are X(n), X(n−1) and X(n−2).

For an L-tap FIR filter, if we use the straightforward precomputation approach as for the 2-tap and 3-tap FIR filters, we need a W-bit S^{L} multiplexer where S is the number of possibilities of the input signal to the L-tap FIR filter. The complexity grows exponentially with L. When L or S is large, the straightforward precomputation is infeasible.

### The Proposed Low Complexity Precomputation Approach for FIR Filters

As pointed in the previous section, the complexity of the straightforward precomputation for an L-tap FIR filter grows exponentially with the number of taps, L. One method to reduce the complexity of the straightforward approach is to just precompute the output of each tap (i.e, to precompute the output of each multiplier in the FIR filter).

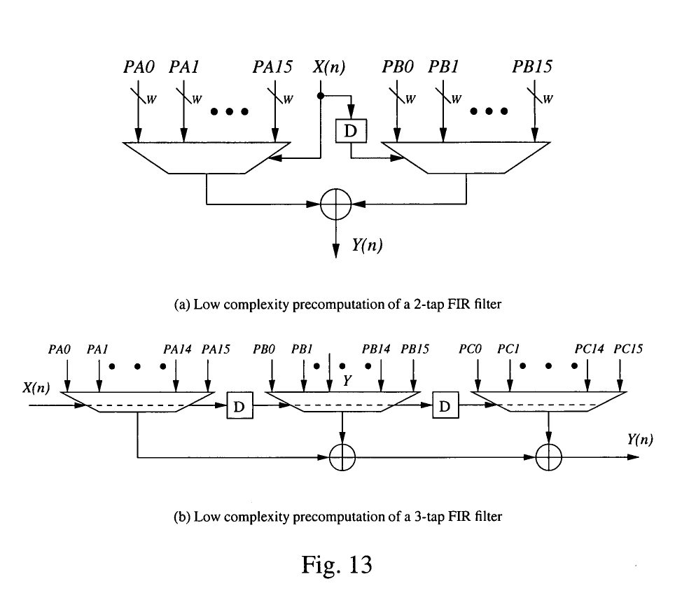

Consider the 2-tap filter in FIG. 11(a) again, we also assume that X(n) has 16 possibilities. Hence, both of the outputs of multipliers I and II have 16 possibilities. Denote the 16 possibilities of the output of multiplier I as PA0, PA1, . . . , PA14 and PA15, and those of the output of multiplier II as PB0, PB1, . . . , PB14 and PB15, respectively. All these quantities can be precomputed. The real output of multiplier I or II can be selected using a W-bit 16-to-1 multiplexer. The two outputs of multipliers I and II are then added. FIG. 13(a) illustrates the proposed approach. If we use this idea, we only need two W-bit 16-to-1 multiplexers and an adder while in the straightforward precomputation, we need a W-bit 256-to-1 multiplexer.

Consider the 3-tap filter in FIG. 12(a). If we replace each multiplier with a W-bit 16-to-1 multiplexer. We can obtain FIG. 13(b). The inputs to each multiplexer are the possible outputs of the corresponding multiplier in FIG. 12(a). The output of the 3-tap filter is obtained by adding all the outputs from the 3 multiplexers. In this low complexity design, we only need three W-bit 16-to-1 multiplexers and two adders while in the straightforward precomputation, we need a W-bit 4096-to-1 multiplexer.

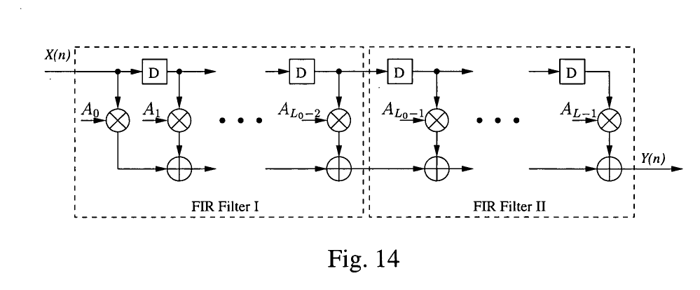

For the L-tap filter in FIG. 14, if we use the proposed low complexity idea, we only need L W-bit S-to-1 multiplexers and L−1 adders when S is the number of possibilities of the input signal of the FIR filter.

For the L-tap filter, we can also combine the straightforward precomputation and the low complexity precomputation approaches. For example, for the L-tap filter shown in FIG. 14. We can divided the L-tap filter into two sub-filters, an L₀-tap FIR filter I and an L−L0-tap FIR filter II, where L₀≦L. For the implementation of the L-tap FIR filter, we can apply the straightforward precomputation method to the L₀-tap filter and the low complexity precomputation method to the L—L0-tap filter.

### Low Complexity Pipelined Tomlinson-Harashima Precoders

In this section, a novel method is proposed to reduce the hardware overhead associated with the precomputation of FIR filter Nₑ(z) in the TH precoder in FIG. 4(b) and the precomputation of FIR filter Nₑ₁(z) in the TH precoder in FIG. 7.

In some applications, the number of levels of v(n) may be very large. Thus, even when we just precompute the first three taps of the FIR filter Nₑ₁(z) as in FIG. 7, the hardware overhead may still be significant. For example, if we assume that v(n) has 16 levels and we want to precompute 3 taps, then we need to totally precompute 16³=4096 candidates and select the actual one by a 4096-to-1 W-bit multiplexer, where W is the wordlength requirement. Thus it is of interest to develop techniques to reduce the hardware complexity associated with precomputation for pipelined TH precoders.

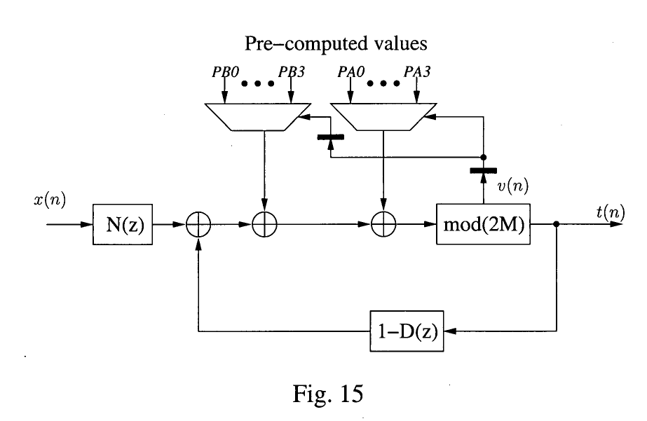

A low complexity pipelined TH precoder can be obtained by applying the proposed low complexity precomputation technique for FIR filters in the previous section to the FIR filter Nₑ(z) in the TH precoder FIG. 4(b) and the FIR filter Nₑ₁(z) in the TH precoder in FIG. 7. Consider FIG. 4(b), we assume Nₑ(z) has two taps and Nₑ(z)=A+Bz⁻¹. In addition, we assume v(n) only has four possibilities. Applying the low complexity precomputation technique to the filter Nₑ(z), we can obtain the low complexity pipelined TH precoder shown in FIG. 15. In that figure, PA0, . . . , and PA3 are the four possibilities for the product of A×v(n−1), and PB0, . . . , and PB3 are those for the product of B×v(n−2). In this proposed design, we only need two W-bit 4-to-1 multiplexers while if we use the straightforward precomputation, a W-bit 16-to-1 multiplexer is needed.

We can also combine the straightforward precomputation and the low complexity precomputation approaches as in the previous section for the FIR filter Nₑ(z) in the TH precoder in FIG. 4(b) and the FIR filter Nₑ₁(z) in the TH precoder in FIG. 7.

### Generalization

The present method to design low complexity pipelined TH precoders can be used to design FIR Tomlinson-Harashima precoder for order more than 2 and pipelining level more than 2.

The present method can also be used in pipelined IIR TH precoders to design low complexity pipelined IIR TH precoders.

### Conclusions

In the present invention, a method to design low complexity precomputation based FIR filters and the architecture for the same are presented. A method to design low complexity pipelined TH precoders and the architecture for the same are presented.

While various embodiments of the present invention have been described above, it should be understood that they have been presented by way of example only, and not limitation. It will be understood by those skilled in the art that various changes in form and details can be made therein without departing from the spirit and scope of the invention as defined in the appended claims. Thus, the breadth and scope of the present invention should not be limited by any of the above-described exemplary embodiments, but should be defined only in accordance with the following claims and their equivalents.

What is claimed is:

1. A method to implement a low complexity precomputation based FIR filter, the method comprising:
(a) precomputing all possible outputs of the multiplier in each tap of the FIR filter;
(b) selecting the result of the multiplier by using a multiplexer whose inputs are the precomputed values in (a),
(c) repeating (a) and (b) for all taps of the filter and adding the results of all tap multipliers obtained in (b) and (c).

2. An FIR filter integrated circuit, containing at least two taps, implemented using,
(a) precomputation of at least two possible values of two tap multipliers,
(b) at least two multiplexers to select at least two multiplier results from the precomputed values in (a),
(c) one adder to add the two results obtained in (b).

3. The integrated circuit in claim 2 as part of a data transmission system over copper,

4. The integrated circuit in claim 2 as part of a data transmission system over fiber,

5. The integrated circuit in claim 2 as part of a data transmission system over wireless,

6. The integrated circuit in claim 2 as part of a data storage system.

7. An integrated circuit to implement a Tomlinson-Harashima precoder, comprising,
(a) A modulo device which outputs a compensation signal with at least two possible values,
(b) precomputation of at least two intermediate results for the first tap multiplier,
(c) precomputation of at least two intermediate results for the second tap multiplier,
(d) a first multiplexer with at least two intermediate results for the first multiplier at its inputs,
(e) a second multiplexer with at least two intermediate results for the second multiplier at its inputs, and
(f) one adder which adds the output of the first multiplexer and the output of the second multiplexer.

8. The integrated circuit in claim 7 as part of a data transmission system over copper,

9. The integrated circuit in claim 7 as part of a data transmission system over fiber,

10. The integrated circuit in claim 7 as part of a data transmission system over wireless,

11. The integrated circuit in claim 7 as part of a data storage system.
